(19) United States
(12) Patent Application Publication
(10) Pub. No.: US 2010/0285655 A1
(43) Pub. Date: Nov. 11, 2010

(54) METHOD OF PRODUCING BONDED WAFER

(75) Inventor: Takashi Sakai, Minato-ku (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/772,840

(22) Filed: May 3, 2010

(30) Foreign Application Priority Data
May 8, 2009 (JP) 2009-113236

(51) Int. Cl. H01L 21/762

(52) U.S. Cl. 438/459; 257/E21.567

(57) ABSTRACT

In the production of a bonded wafer by bonding a silicon wafer for active layer with an internal oxide film to a silicon wafer for support layer directly or indirectly with an insulating layer to form a silicon wafer composite and removing an upperlayer-side silicon portion and the internal oxide film of the silicon wafer composite to leave only an active layer with a given thickness, the active layer forming step is conducted only by polishing under given conditions.

### BACKGROUND OF THE INVENTION

1. Field of the Invention

This invention relates to a technique for producing a bonded wafer, especially a bonded wafer requiring thinning of an active layer such as a thin-film bonded SOI wafer, a backside illumination type CMOS image sensor or the like, and also to a technique for forming a substrate side the active layer at a desired thickness by polish processing.

2. Description of the Related Art

The wafer bonding technique is employed in the production of various semiconductor wafers. For example, the SOI wafer is produced by bonding a silicon wafer for active layer to a silicon wafer for support layer through an insulating film and thereafter grinding and polishing the silicon wafer for active layer to render the active layer into a desired thickness. Also, in order to cope with needs for miniaturization and lower power consumption of a device, it is increasingly apt to develop a DSB wafer by directly bonding two silicon wafers to each other without an insulating film.

In accordance with the higher integration and the high-speed operation of a semiconductor device, and further with the development of new applications, there is a significant tendency of thinning and planarization of an active layer in a bonded wafer. For example, in the production step of a backside illumination type CMOS image sensor, it is required to reduce the thickness of an active layer to not more than 0.3 μm and the surface roughness thereof to not more than 2.0 rms (nm).

In the production of a bonded wafer having an extremely-thin and planarized active layer as mentioned above, it is necessary to develop a new production technique, especially a new technique for grinding and polishing an active layer of a silicon wafer for active layer to desired flatness and thickness after the silicon wafer for active layer is bonded to a silicon wafer for support layer. Bearing in mind that products are industrially mass-produced, it is also necessary to consider not only the higher accuracy of products but also the production efficiency and the cost reduction in the development of the new production technique.

Presently, the technique described in WO 2005/074033 is known as the technique for producing a bonded wafer having an extremely-thinned and planarized active layer. In this technique, it is possible to conduct the thinning and thickness uniformization of an active layer by bonding a silicon wafer for active layer having an oxygen ion implanted layer to a silicon wafer for support layer, changing the oxygen ion implanted layer into an SiO₂ layer (oxide film) through heat treatment, grinding and polishing from the side of the silicon wafer for active layer to the SiO₂ layer (oxide film) with an alkali polishing solution, and thereafter removing the SiO₂ layer (oxide film).

The oxygen ion implanted layer acts as a polishing stop layer. That is, when mechano-chemical polishing is conducted with the alkali polishing solution as above, an etching rate difference is caused between silicon and the SiO₂ layer (oxide film). In the above technique, the active layer is polished to a desired thickness by using such an etching rate difference to detect timing for stopping the polishing of the active layer.

In the technique described in WO 2005/074033, however, there is adopted means for removing the SiO₂ layer (oxide film) by grinding and polishing from the side of the silicon wafer for active layer to the SiO₂ layer (oxide film) with the alkali polishing solution, subjecting the bonded wafer to an oxidation treatment through heating in an oxidizing atmosphere at 600° C. to 1000° C., and thereafter etching the SiO₂ layer (oxide film) with a HF solution. That is, in the technique described in WO 2005/074033, the grinding-polishing step and etching step with an HF solution are required for forming an active layer having desired flatness and thickness. Thus, the operation is complicated, which leaves a problem in terms of the production efficiency.

In the production process of, for example, a backside illumination type CMOS image sensor, an SiO₂ layer (oxide film) is provided on a silicon wafer for active layer, and an epitaxial layer is produced thereon and a device is formed on the epitaxial layer, and thereafter the silicon wafer for active layer is bonded to a silicon wafer for support layer, and then an upper layer side silicon portion and the SiO₂ layer (oxide film) are removed. In such a bonded wafer, the epitaxial layer provided with the device is existent just beneath the SiO₂ layer (oxide film), so that the technique described in WO 2005/074033 requiring a high temperature oxidation treatment can not be adopted in the removal of the SiO₂ layer (oxide film). Because, the device in the epitaxial layer formed just beneath the SiO₂ layer (oxide film) is deteriorated during the high temperature oxidation treatment.

Furthermore, it is necessary to consider the reduction of oxygen ion dose amount in the formation of the SiO₂ layer (oxide film) for reducing costs for the production process. However, when the oxygen ion dose amount is reduced, an etching rate difference between silicon and SiO₂ (oxide film) becomes small. That is, since the reduction of oxygen ion dose amount tends to make the structure of the oxide film incomplete (sparse), it is not possible to detect timing at which the polishing should be stopped when a polishing surface arrives in an active layer, and the SiO₂ layer (oxide film) may not function as a polishing stop layer.

### SUMMARY OF THE INVENTION

It is, therefore, an object of the invention to provide a method of producing a bonded wafer which enables the high accuracy of products, the improvement of production efficiency and the reduction of cost and is further applicable to the production process of a backside illumination type CMOS image sensor and the like.

The inventor has made various studies in order to solve the above problems in the conventional technique. As a result, there are obtained the followings (a) and (b) on the technique for producing a bonded wafer.

(a) When a bonded wafer having an active layer with a given thickness is produced from a silicon wafer composite formed by bonding a silicon wafer for active layer to a silicon wafer for support layer, an SiO₂ layer (oxide film) as a polishing stop layer is removed only by a polishing step without an etching step using hydrofluoric acid or the like, which eliminates complication of operation and is further applicable to the production process for a backside illumination type CMOS image sensor and the like.

(b) Even when the oxygen ion dose amount is reduced in the formation of an SiO₂ layer (oxide film), an alkali polishing solution is used in the above polishing step and the full polishing process from rough polishing to finish polishing is conducted with a polishing cloth typically used in the finish polishing, whereby it is made possible to detect the difference in an etching rate between silicon and SiO₂ layer (oxide film).

The invention is based on the above knowledge and the summary and construction thereof are as follows:

1. A method of producing a bonded wafer by comprising steps of bonding a silicon wafer for active layer having an internal oxide film positioned inside an active layer to be formed to a silicon wafer for support layer directly or indirectly with an insulating layer to form a silicon wafer composite and removing an upperlayer-side silicon portion and the internal oxide film of the silicon wafer composite from a part corresponding to the silicon wafer for active layer in the silicon wafer composite to leave only an active layer with a given thickness, wherein the active layer forming step is conducted only by polishing under given conditions.

2. A method of producing a bonded wafer according to the item 1, wherein the polishing comprises a first polishing step for removing the upperlayer-side silicon portion until reaching the internal oxide film, a second polishing step for removing the internal oxide film and a third polishing step for forming an active layer with a given thickness.

3. A method of producing a bonded wafer according to the item 1 or 2, wherein the polishing is conducted by a mechano-chemical polishing method using a rotating platen provided with a polishing cloth and performing polishing while supplying an alkali polishing solution, and an abrasive concentration of the alkali polishing solution is less than 0.1 mass % in the first polishing step, not less than 0.1 mass % in the second polishing step and less than 1.0 mass % in the third polishing step.

4. A method of producing a bonded wafer according to the item 3, wherein the polishing cloth is a polishing cloth formed by impregnating a nonwoven cloth with urethane and conducting wet expansion.

5. A method of producing a bonded wafer according to the item 2, wherein the first polishing step is conducted by detecting a fact that the upperlayer-side silicon portion is polished till a part of the polished surface arrives in the internal oxide film with a variation of polish processing torque.

6. A method of producing a bonded wafer according to the item 1, wherein the internal oxide film is formed by implanting oxygen ions at a small dose amount into a given depth position from a surface of the silicon wafer for active layer without conducting subsequent high temperature oxidizing treatment.

7. A method of producing a bonded wafer according to the item 6, wherein the dose amount of oxygen ions for the internal oxide film is not more than 1.3×10¹⁷/cm².

8. A method of producing a bonded wafer according to the item 1, wherein the bonded wafer is a wafer used in a backside illumination type CMOS image sensor.

According to the invention, when a bonded wafer having an active layer with a given thickness is produced from a silicon wafer composite formed by bonding a silicon wafer for active layer to a silicon wafer for support layer, an SiO₂ layer (oxide film) as a polishing stop layer is removed by a polishing step without conducting an etching step with hydrofluoric acid or the like, which eliminates complication of operation and improves the production efficiency. Also, the SiO₂ layer (oxide film) can be removed with a high accuracy without conducting a high temperature oxidizing treatment for making a structure of the SiO₂ layer (oxide film) complete (dense), which is applicable to the production process for a backside illumination type CMOS image sensor and the like. Furthermore, the oxygen ion dose amount can be reduced in the formation of the SiO₂ layer (oxide film) acting as a polishing stop layer. Thus, the invention is an effective method for reducing costs of products.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The invention will be described with reference to the accompanying drawings, wherein:

FIGS. 1(A) to 1(C) are graphs showing a relation between oxygen ion dose amount for a polishing stop layer and polish processing torque variation, respectively;

FIGS. 2(A1) and 2(A2) are diagrams illustrating a surface condition of an active layer constituting a bonded silicon wafer of Invention Example;

FIGS. 2(B1) and 2(B2) are diagrams illustrating a surface condition of an active layer constituting a bonded silicon wafer of Comparative Example;

FIG. 3 is a graph showing a surface roughness of a polished surface in each bonded silicon wafer of Comparative Examples and Invention Examples;

FIGS. 4(A1) and 4(A2) are diagrams illustrating a distribution state of surface roughness in a bonded silicon wafer in Invention Example; and

FIGS. 4(B1) and 4(B2) are diagrams illustrating a distribution state of surface roughness in a bonded silicon wafer in Comparative Example.

### DESCRIPTION OF THE PREFERRED EMBODIMENTS

The method of producing a bonded wafer according to the invention is a method of producing a bonded wafer by comprising steps of bonding a silicon wafer for active layer having an internal oxide film positioned inside an active layer to be formed to a silicon wafer for support layer directly or indirectly with an insulating layer to form a silicon wafer composite and removing an upperlayer-side silicon portion and the internal oxide film of the silicon wafer composite from a part corresponding to the silicon wafer for active layer in the silicon wafer composite to leave only an active layer with a given thickness, wherein the active layer forming step is conducted only by polishing under given conditions.

The silicon wafer for active layer and silicon wafer for support layer used in the invention are not particularly limited irrespective of the kind thereof as long as they have a surface roughness suitable for bonding, and a silicon single crystal having, for example, a bonded crystal face of (100), (110) or (111) is applicable.

As the method of forming the internal oxide film (polishing stop layer) in the silicon wafer for active layer can be used, for example, a method of implanting oxygen ions.

The silicon wafer composite formed by bonding the silicon wafer for active layer to the silicon wafer for support layer indirectly with an insulating layer forms an SOI wafer through subsequent steps. On the other hand, the silicon wafer composite formed by directly bonding both the wafers without an insulating layer forms a DSB wafer through subsequent steps.

As the insulating layer is preferable an oxide layer (SiO₂), a nitride layer (Si₃N₄) or the like. As the method of forming the insulating layer are mentioned, for example, a method in which either of the silicon wafer for active layer and the silicon wafer for support layer or both thereof is subjected to a heat oxidizing treatment or a heat nitriding treatment at a step before the bonding, a method in which an SiO₂ layer or an Si₃N₄ layer is formed by CVD, and so on. Moreover, the insulating layer may be formed before or after the internal oxide film is formed in the silicon wafer for active layer.

After the silicon wafer for active layer and the silicon wafer for support layer are bonded to each other at their predetermined surfaces, a heat treatment for strengthening the bonding is conducted to form a silicon wafer composite. As the bonding method are mentioned bonding under vacuum, bonding through plasma and the like. Moreover, the heat treating condition for strengthening the bonding is preferable to be 1000 to 1200° C. in an oxidizing atmosphere for 60 to 180 minutes. In order to suppress defects such as voids and the like on the surface to be bonded, it is preferable to conduct a cleaning treatment on the bonding surfaces of the silicon wafer for active layer and the silicon wafer for support layer to remove extraneous substances from the bonding surfaces before the bonding.

Subsequently, the silicon wafer composite is subjected to an active layer forming step in which an upperlayer-side silicon portion and the internal oxide film (polishing stop layer) are removed to leave only an active layer with a given thickness, whereby there is provided a bonded wafer having a desired active layer. Here, it should be particularly remarked that the above active layer forming step is conducted only by polishing. As previously mentioned, the etching is employed as a method of removing the internal oxide film (polishing stop layer) in the conventional technique, which causes the deterioration of production efficiency. Moreover, the above etching associated with a high temperature oxidizing treatment and using HF as an etching solution is not suitable for a process of producing a backside illumination type CMOS image sensor or the like. The invention is significantly effective as a solution of the above problem in the conventional method.

The polishing can be conducted using various polishing devices. For example, it is preferable to use a polishing device provided with a rotating platen having a polishing cloth on its surface and a support head for supporting a work to impose a polishing face of the work onto the polishing cloth while supplying a polishing solution, especially a single-wafer type polishing device capable of polishing a silicon wafer composite one by one. Also, it is preferable that the polishing comprises the first polishing step for removing the upperlayer-side silicon portion until reaching the internal oxide film (polishing stop layer), the second polishing step for removing the internal oxide film and the third polishing step for forming an active layer with a given thickness and desired conditions are selected in each of the polishing steps for polishing. Moreover, it is preferable that the total polishing amount from the first polishing step to the third polishing step is 0.1 to 50 μm for developing the effects by the method of the invention.

The polishing is preferable to be mechano-chemical polishing with an alkali polishing solution. When alkali polishing solution is used, an etching rate difference is easily caused between silicon and an SiO₂ layer (internal oxide film) and the internal oxide film functions effectively as a polishing stop layer. As the alkali polishing solution can be used, for example, an inorganic alkali solution (KOH, NaOH or the like), an organic alkali solution composed mainly of amine (piperazine, ethylene diamine or the like) and so on. Moreover, colloidal silica or the like is mentioned as an abrasive contained in the alkali polishing solution, and an abrasive concentration is preferable to be not more than 10 mass %.

In the first polishing step for polishing the upperlayer-side silicon portion of the silicon wafer composite, it is preferable to use an alkali polishing solution having an abrasive concentration of less than 0.1 mass %, and it is more preferable that the abrasive concentration is less than 0.05 mass %. Although it is required in the first polishing step to detect an arrival timing of a part of the polished surface in the internal oxide film (polishing stop layer) based on an etching rate difference, when the abrasive concentration is less than 0.1 mass %, chemical polishing becomes more dominant than mechanical polishing, resulting in the significant etching rate difference. The lower limit of the abrasive concentration is not particularly limited, and no abrasive may be contained. Even in case of containing no abrasive, there is no difference in silicon polishing rate as compared with a case having an abrasive concentration of not less than 0.1 mass %, and it is rather preferable in a point that polishing damages by abrasives are suppressed. Moreover, organic substances, oxide films and the like may be existent on the surface of the silicon wafer composite before polishing. In such a case, it is also possible to conduct polishing with an alkali polishing solution having an abrasive concentration of not less than 0.1 mass % in only an initial stage of the first polishing step for the purpose of removing these substances efficiently. After the detection of the etching rate difference, the polishing conditions are changed for transferring to the second polishing step.

In the second polishing step for polishing the internal oxide film (polishing stop layer), it is preferable to use an alkali polishing solution having an abrasive concentration of not less than 0.1 mass % and it is more preferable that the abrasive concentration is not less than 0.3 mass %. In the second polishing step, there is no need to detect the etching rate difference, and the higher abrasive concentration makes mechanical polishing more dominant, which leads to the effective polishing of the internal oxide film (polishing stop layer). Moreover, it is preferable that the abrasive concentration is not more than 10.0 mass % in the respects of suppressing the occurrence of flaws on the wafer due to the abrasives and ensuring the pH stability of the alkali polishing solution and suppressing the condensation. After the internal oxide film (polishing stop layer) is removed in the second polishing step, the polishing conditions are changed for transferring to the third polishing step.

In the third polishing step for finish-polishing the polished surface after the removal of the internal oxide film (polishing stop layer), it is preferable to use an alkali polishing solution having an abrasive concentration of less than 1.0 mass % and it is more preferable that the abrasive concentration is less than 0.5 mass %. By lowering the abrasive concentration can be formed an active layer having a given thickness with a high accuracy but also the finish-polished surface (surface of the active layer) can be planarized. Also, ammonia or the like is preferably selected as an alkali polishing solution. Although the lower limit of the abrasive concentration is not particularly limited, the concentration of not less than 0.1 mass % is preferable in terms of adjusting the surface roughness of the wafer.

The polishing cloth is preferable to be ones formed by impregnating a nonwoven cloth with urethane and conducting wet expansion since the etching rate difference occurs more easily. That is, the invention is based on a new knowledge that a polishing cloth typically used in the finish polishing step is also applied to the rough polishing step to facilitate the detection of the etching rate difference between silicon and SiO₂ layer (internal oxide film). As the polishing cloth formed by impregnating a nonwoven cloth with urethane and conducting wet expansion are used the well-known ones.

In the first polishing step, it is necessary to detect the arrival of a part of the polished surface in the internal oxide film (polishing stop layer) based on an etching rate difference between silicon and SiO₂ layer (internal oxide film). As such a detection means is exemplified, for example, means for polishing while measuring polish processing torque.

As previously mentioned, the polishing in the active layer forming step is conducted using a polishing device or the like provided with a rotating platen having a polishing cloth on its surface and a support head for supporting a work to impose a polishing face of the work onto the polishing cloth while supplying a polishing solution. In the invention, a polishing surface of a silicon wafer composite as a work is imposed onto the polishing cloth located on the surface of the rotating platen and polished while rotating the rotating platen, which produces polish processing torque in the rotating platen (and support head) resulting from frictional force between the polishing cloth and the polishing surface.

Here, when mechano-chemical polishing is conducted while supplying the alkali polishing solution having an abrasive concentration of less than 0.1 mass % as mentioned above, the frictional force is significantly dependent on an etching rate of the work. Also, when the polishing is carried out with the alkali polishing solution as described above, the etching rate differs between silicon and an SiO₂ layer (internal oxide film), and silicon shows a higher etching rate. Thus, when the silicon wafer composite is polished while supplying the alkali polishing solution, as the polished surface arrives in a part of the internal oxide film, the frictional force between the polishing cloth and the polishing surface increases and polish processing torque also rises associated therewith. In the invention, therefore, the arrival of the polished surface in a part of the internal oxide film can be detected simply with a high accuracy by polishing the upperlayer-side silicon portion of the silicon wafer composite while measuring polish processing torque in the first polishing step to check polish processing torque variation.

The method of detecting the polish processing torque variation is not particularly limited, and there can be employed various methods such as a method of detecting the variation of a current value of an electric motor which provides a driving force for the rotating platen in the polishing device, a method of detecting the variation of a torsion value generated in a rotating axis of the rotation platen, a method of detecting the variation of a vibration value of the rotating platen and so on.

In the invention, when the internal oxide film is formed in the silicon wafer for active layer, it is possible to employ a known method in which oxygen ions are implanted into a given depth position from the surface of the silicon wafer for active layer to form an internal oxide film. In this case, it is preferable that an oxygen ion dose amount is reduced as much as possible, concretely to not more than 1.3×10¹⁷/cm² from a viewpoint of the cost reduction. Although the lower limit of the oxygen ion dose amount is not particularly limited, it is preferable to be not less than 1.0×10¹⁶/cm² since stable torque detection is enabled.

When the oxygen ion dose amount is large, the internal oxide film in the silicon wafer for active layer becomes a complete oxide film. When the oxygen ion dose amount is reduced, the internal oxide film in the silicon wafer for active layer becomes an incomplete oxide film. Here, the etching rate in the mechano-chemical polishing is different according to whether the internal oxide film is a perfect oxide film or an imperfect oxide film, and the etching rate becomes higher in the latter case. As a result, a difference from the etching rate of silicon is small. Thus, when the oxygen ion dose amount is reduced, it becomes difficult to detect an etching rate difference between silicon and SiO₂ (internal oxide film). In the conventional method, therefore, the internal oxide film does not function as a polishing stop layer unless the high temperature oxidizing treatment is performed when the oxygen ion dose amount is less than 1.3×10¹⁷/cm².

In the invention, however, the upperlayer-side silicon portion of the silicon wafer composite is polished while detecting the polish processing torque variation in the first polishing step, so that it is possible to detect an arrival timing of a part of the polished surface in the internal oxide film (polishing stop layer) with a high accuracy. Particularly, in the invention, the polishing conditions usually used in the finish polishing, that is, an alkali polishing solution having an abrasive concentration of less than 0.1% and a polishing cloth formed by impregnating a nonwoven cloth with urethane and conducting wet expansion are used in the first polishing step of rough polishing to make a state of easily detecting a tiny variation of polish processing torque, whereby the arrival timing of a part of the polished surface in the internal oxide film (polishing stop layer) can be detected with a higher accuracy.

As mentioned above, according to the invention, the active layer forming step for forming a bonded silicon wafer having an active layer with a given thickness from a silicon wafer composite formed by bonding a silicon wafer for active layer to a silicon wafer for support layer can be conducted by only the polishing. That is, the invention is significantly advantageous in view of operation efficiency and productivity as compared with the conventional method of removing the internal oxide film (polishing stop layer) by HF etching with a high temperature heat treatment, because it is possible to perform the active layer forming step on the single rotating platen.

The conventional method of removing the internal oxide film (polishing stop layer) by HF etching with a high temperature heat treatment is not suitable for the production process of a backside illumination type CMOS image sensor having an epitaxial layer with a device formed just beneath the SiO₂ layer (oxide film) because it is required to conduct the high temperature heat treatment for forming a complete internal oxide film. According to the invention, even if the internal oxide film (polishing stop layer) is imperfect, it is removed by polishing, so that the invention is preferably used in the production process of a backside illumination type CMOS image sensor and the like.

In the invention, even when the oxygen ion dose amount in the formation of the internal oxide film is smaller than usual and the internal oxide film is an extremely-thin and imperfect oxide film, the arrival timing of a part of the polished surface in the internal oxide film can be detected with a high accuracy. Therefore, the invention is significantly effective as a means for attaining the higher accuracy and lower cost of a bonded wafer provided with an extremely-thin and flat active layer.

Next, the effects of the invention will be explained using examples and comparative examples. The examples are merely exemplified for explaining the invention, and do not limit the invention.

First, there is prepared a silicon wafer composite by bonding a silicon wafer for active layer to a silicon wafer for support layer according to the following procedures.

Oxygen ions are implanted from a surface of a P+(111) wafer having a diameter of 300 mm at a wafer temperature of 400° C. and an accelerating voltage of 216 keV to prepare a silicon wafer for active layer with each oxygen ion dose amount of 2.0×10¹⁷/cm², 1.3×10¹⁷/cm², 6.5×10¹⁶/cm² and 1.0×10¹⁶/cm². Each of these silicon wafers is subjected to pre-annealing in an Ar atmosphere at 1200° C. for 1 hour and subsequently to a heat treatment in a steam atmosphere at 950° C. for 4 hours to form an insulating layer having a thickness of 150 nm.

On the other hand, as a silicon wafer for support layer is provided a P−(100) wafer having a diameter of 300 mm.

The silicon wafer for active layer and the silicon wafer for support layer are subjected to cleaning before bonding (cleaning agent: SC1). Subsequently, the oxygen ion implanted surface of the silicon wafer for active layer is bonded to one surface of the silicon wafer for support layer through a plasma bonding method, which is subjected to a heat treatment for strengthening the bonding in a steam atmosphere at 350° C. for 10 hours to obtain a silicon wafer composite.

### Test Example 1

With respect to each of the silicon wafer composites having an internal oxide film (polishing stop layer) formed at a different oxygen ion dose amount through an oxygen ion implantation method as mentioned above, a surface grinding with a grinding stone of #300 is performed to remove a residual film (10 μm) of a portion corresponding to the silicon wafer for active layer, and then an alkali etching (etching solution: KOH) is conducted to remove a process-damaged layer (3 μm). Thereafter, a surface to be polished (a surface after the removal of the process-damaged layer) is imposed onto a rotating platen provided with a polishing cloth, and the rotating platen and a support head for supporting the wafer are rotated in the same direction with the revolution number of the rotating platen of 30 rpm and the revolution number of the support head of 31 rpm, whereby the upperlayer-side silicon of the silicon wafer composite is polished while detecting a variation amount of polish processing torque (first polishing step). The variation amount of polish processing torque is determined by measuring a motor current value of the rotating platen during polishing and converting the current value into a polish processing torque to gain a time differential value. Moreover, the polishing solution and polishing cloth used are as follows:

Polishing solution: KOH polishing solution having an abrasive concentration of 0.01 mass % (abrasive: colloidal silica)

Polishing cloth: polishing cloth (suede type) formed by impregnating a nonwoven cloth with urethane and conducting wet expansion.

### Test Example 2

The upperlayer-side silicon portion of the silicon wafer composite is polished under the same conditions as in Test Example 1 except that the polishing cloth is changed to a velour-type polishing cloth.

### Test Example 3

The upperlayer-side silicon portion of the silicon wafer composite is polished under the same conditions as in Test Example 1 except that the abrasive concentration of the alkali polishing solution is changed to 0.75 mass %.

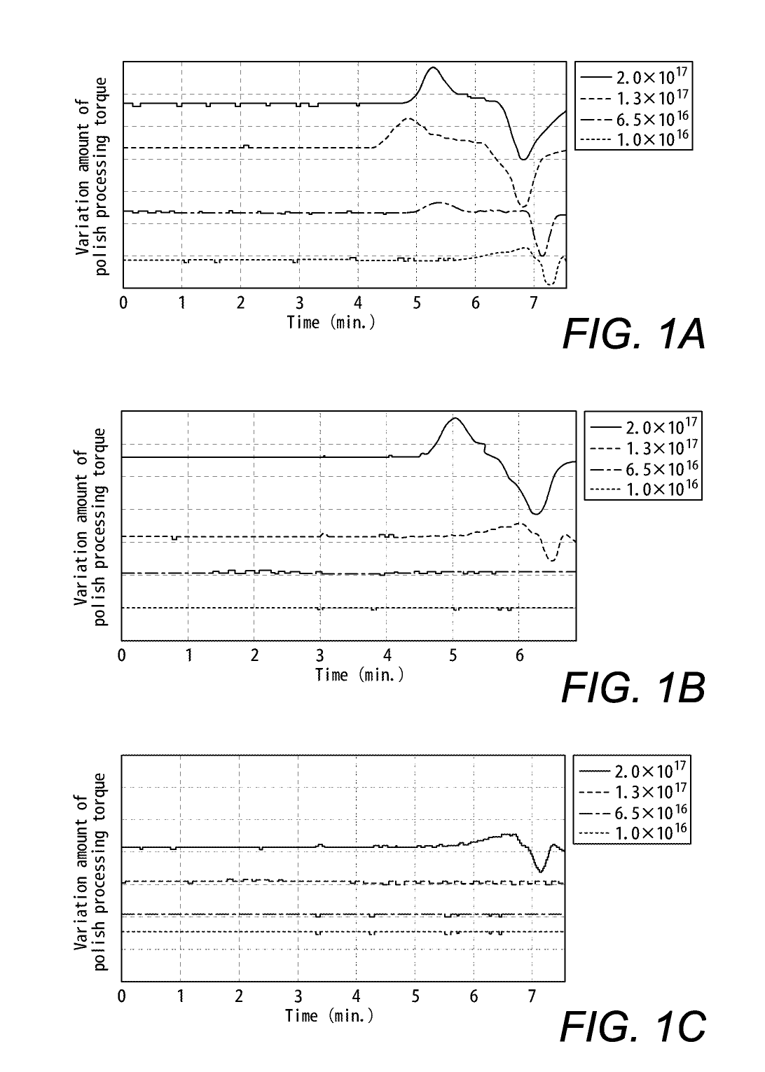

FIGS. 1(A) to 1(C) are graphs showing the variation amount of polish processing torque detected in Test Examples 1 to 3, respectively.

FIG. 1(A) is a graph showing the variation amount of polish processing torque detected in Test Example 1. As seen from FIG. 1(A), in Test Example 1 in which the abrasive concentration is set to be less than 0.1 mass % and a polishing cloth formed by impregnating a nonwoven cloth with urethane and conducting wet expansion is used, the significant variation amount of polish processing torque is shown even when the oxygen ion dose amount is reduced to 1.0×10¹⁶/cm² and it is possible to grasp an arrival timing of a part of the polished surface in the internal oxide film (polishing stop layer).

Also, FIG. 1(B) is a graph showing the variation amount of polish processing torque detected in Test Example 2. In Test Example 2 in which the abrasive concentration is set to be less than 0.1 mass % and a velour type polishing cloth is used, the variation amount of polish processing torque is not as significant as in Test Example 1, but it is possible to grasp an arrival timing of a part of the polished surface in the internal oxide film (polishing stop layer) even when the oxygen ion dose amount is reduced to 1.3×10¹⁷/cm².

On the other hand, FIG. 1(C) is a graph showing the variation amount of polish processing torque detected in Test Example 3. As seen from FIG. 1(C), in Test Example 3 using an alkali polishing solution with a high abrasive concentration, it is not possible to grasp an arrival timing of a part of the polished surface in the internal oxide film (polishing stop layer) as the oxygen ion dose amount is reduced to 1.3×10¹⁷/cm².

### Example 1

A silicon wafer composite with an oxygen ion dose amount of 6.5×10¹⁶/cm² is polished under the same conditions as in Test Example 1. Then, the polishing is stopped at a timing that the variation amount of polish processing torque decreases and thereafter increases to be stable. Then, the alkali polishing solution is changed to a KOH polishing solution having an abrasive concentration of 0.3 mass % (abrasive: colloidal silica), and the polishing is restarted to remove the internal oxide film (polishing stop layer) (second polishing step). After the removal of the internal oxide film (polishing stop layer), the polishing is stopped and the polishing solution is changed to an ammonia-based alkali (ammonia water) having an abrasive concentration of 0.5 mass % (abrasive: colloidal silica) and containing a polymer, and thereafter the polishing is restarted as finish polishing to prepare a bonded silicon wafer (third polishing step).

### Comparative Example 1

A silicon wafer composite with an oxygen ion dose amount of 6.5×10¹⁶/cm² is polished under the same conditions as in Test Example 2 to remove the internal oxide film (polishing stop layer). Moreover, the polishing stop timing is determined based on an arrival timing in the internal oxide film (polishing stop layer) calculated from a polishing rate.

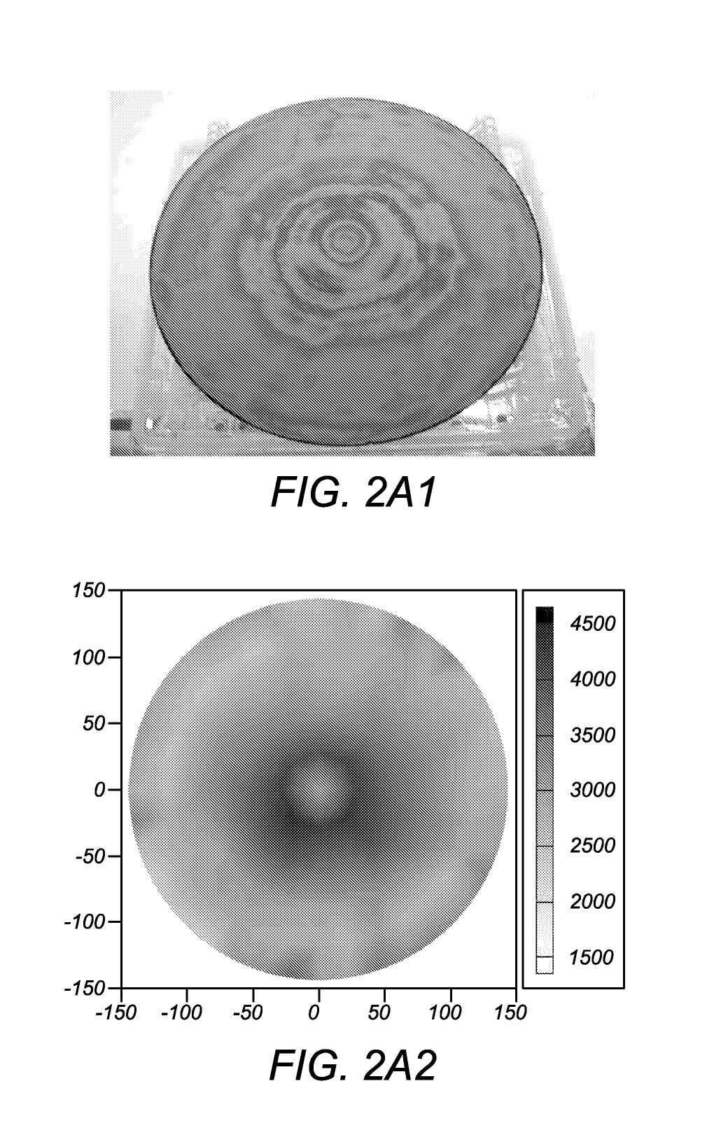

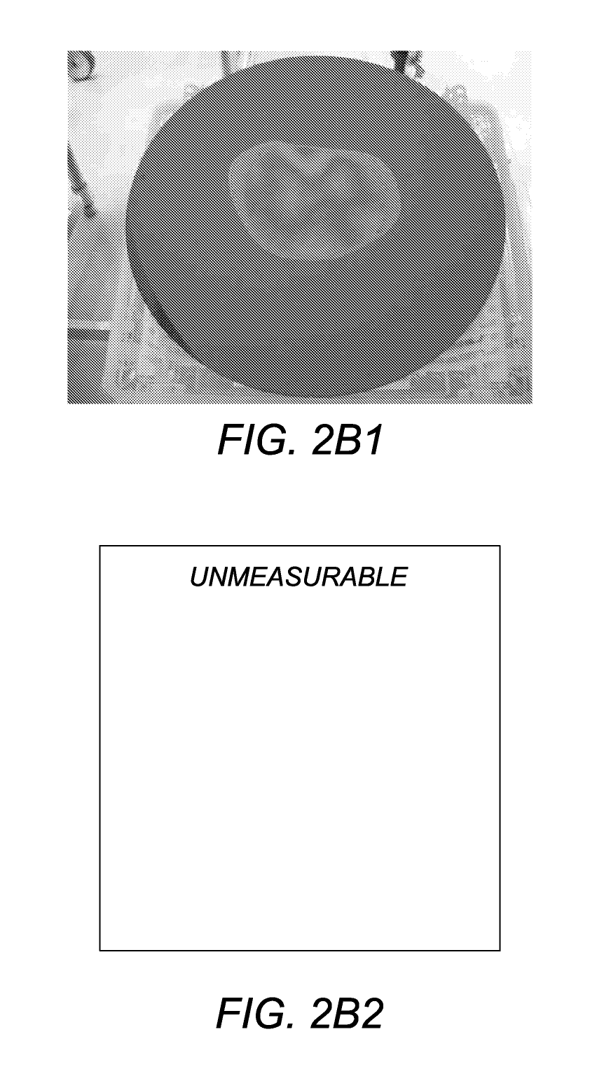

With respect to the bonded silicon wafers prepared in Example 1 and Comparative Example 1 are shown conditions of polished surfaces in FIGS. 2(A) and 2(B), respectively. FIG. 2(A1) shows a polished surface of the bonded silicon wafer prepared in Example 1. As seen from FIG. 2(A1), a desired active layer is left on the whole of the polished surface of the bonded silicon wafer prepared in Example 1 according to the invention. Also, the thickness of the active layer is 2600 Å (average value) as measured by ellipsometry, and the scattering of the thickness is 2151 Å. Moreover, the scattering of the thickness is defined by measuring the thickness of the active layer in the wafer after the polishing at 121 points of the wafer polished surface and taking a difference between maximum value and minimum value of the measured values.

On the other hand, FIG. 2(B1) shows a polished surface of the bonded silicon wafer prepared in Comparative Example 1. As seen from FIG. 2(B1), in Comparative Example 1, the variation amount of polish processing torque is not detected even when a part of the polished surface arrives in the internal oxide film (polishing stop layer) in the first polishing step, so that a part of the active layer just beneath the internal oxide film (polishing stop layer) is also observed to be removed by polishing. As the thickness of the active layer is measured by ellipsometry, the thickness in the central portion of the wafer is 700 Å, and the active layer in the peripheral portion is completely removed.

### Example 2

Six bonded silicon wafers are prepared from a silicon wafer composite with an oxygen ion dose amount of 1.3×10¹⁷/cm² under the same conditions as in Example 1.

### Comparative Example 2

Six bonded silicon wafers are prepared from a silicon wafer composite with an oxygen ion dose amount of 1.3×10¹⁷/cm² under the same conditions as in Example 1 except that the internal oxide film (polishing stop layer) is removed by etching under the following conditions.

Etching agent: HF (concentration 10%)

Treating temperature: room temperature

Treating time: 20 minutes

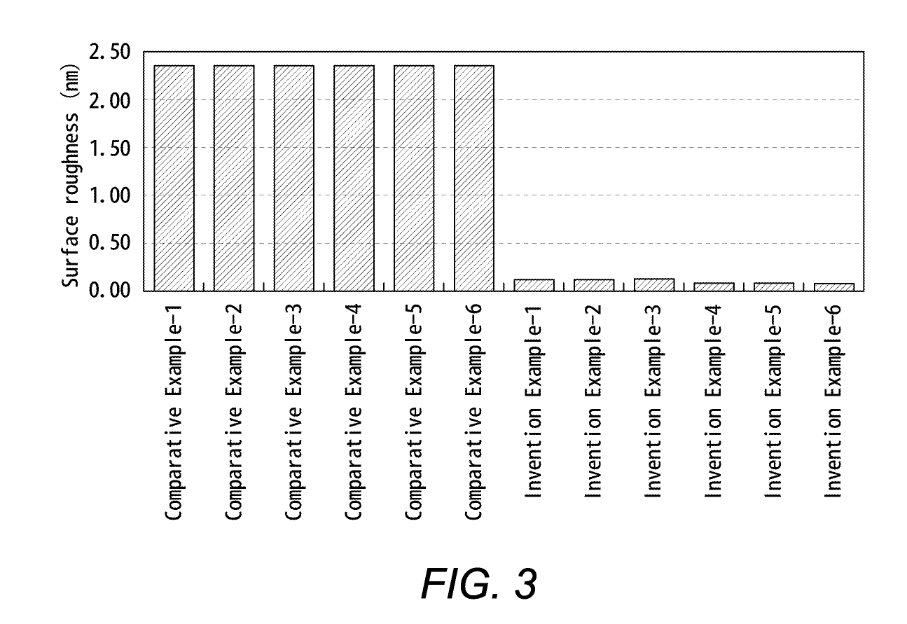

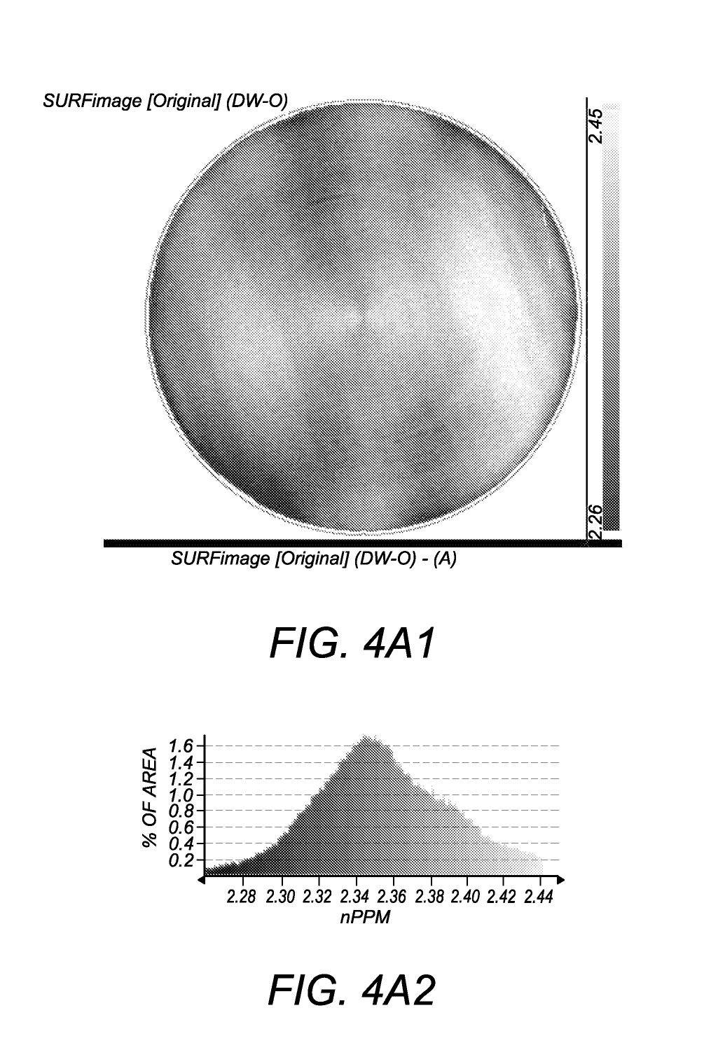

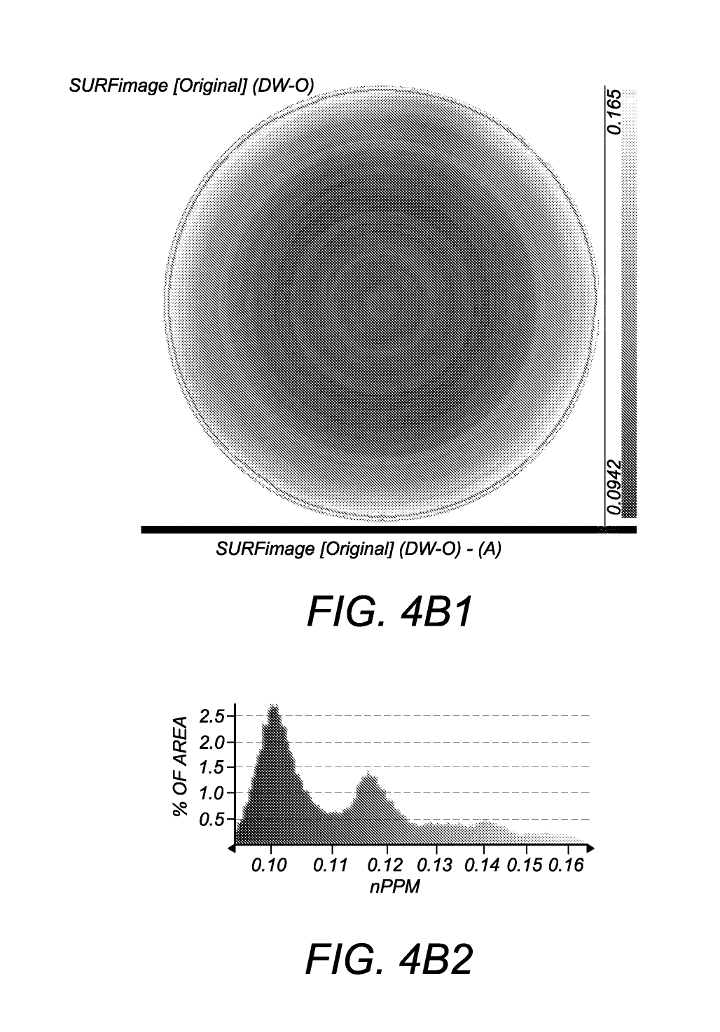

With respect to each of the bonded silicon wafers prepared in Example 2 and Comparative Example 2 is measured the surface roughness (measuring device: Surfscan SP2 made by KLA-Tencor). The measured results are shown in FIG. 3. Also, with respect to each of the bonded silicon wafers prepared in Example 2 and Comparative Example 2 are shown conditions of the polished surfaces in FIGS. 4(A) and 4(B).

As seen from FIG. 3 and FIGS. 4(A) and 4(B), the surface roughness of the bonded silicon wafers in Comparative Example 2, in which the internal oxide film (polishing stop layer) is removed by etching (FIGS. 4(B1,B2)), exceeds 2.00 nm. On the other hand, the bonded silicon wafers prepared in Example 2 according to the invention, in which the active layer forming step is conducted by only polishing (FIGS. 4(A1,A2)), have a surface roughness of less than 0.2 nm and show a very excellent flatness.

There is provided a method of producing a bonded wafer which enables the improvement of production efficiency and the reduction of cost and is further applicable to the production process of a backside illumination type CMOS image sensor and the like.

What is claimed is:

1. A method of producing a bonded wafer by comprising steps of bonding a silicon wafer for active layer having an internal oxide film positioned inside an active layer to be formed to a silicon wafer for support layer directly or indirectly with an insulating layer to form a silicon wafer composite and removing an upperlayer-side silicon portion and the internal oxide film of the silicon wafer composite from a part corresponding to the silicon wafer for active layer in the silicon wafer composite to leave only an active layer with a given thickness, wherein the active layer forming step is conducted only by polishing under given conditions.

2. A method of producing a bonded wafer according to claim 1, wherein the polishing comprises a first polishing step for removing the upperlayer-side silicon portion until reaching the internal oxide film, a second polishing step for removing the internal oxide film and a third polishing step for forming an active layer with a given thickness.

3. A method of producing a bonded wafer according to claim 1 or 2, wherein the polishing is conducted by a mechano-chemical polishing method using a rotating platen provided with a polishing cloth and performing polishing while supplying an alkali polishing solution, and an abrasive concentration of the alkali polishing solution is less than 0.1 mass % in the first polishing step, not less than 0.1 mass % in the second polishing step and less than 1.0 mass % in the third polishing step.

4. A method of producing a bonded waver according to claim 3, wherein the polishing cloth is a polishing cloth formed by impregnating a nonwoven cloth with urethane and conducting wet expansion.

5. A method of producing a bonded wafer according to claim 2, wherein the first polishing step is conducted by detecting a fact that the upperlayer-side silicon portion is polished till a part of the polished surface arrives in the internal oxide film with a variation of polish processing torque.

6. A method of producing a bonded wafer according to claim 1, wherein the internal oxide film is formed by implanting oxygen ions at a small dose amount into a given depth position from a surface of the silicon wafer for active layer without conducting subsequent high temperature oxidizing treatment.

7. A method of producing a bonded wafer according to claim 6, wherein the dose amount of oxygen ions for the internal oxide film is not more than 1.3×10¹⁷/cm².

8. A method of producing a bonded wafer according to claim 1, wherein the bonded wafer is a wafer used in a backside illumination type CMOS image sensor.
